(19) United States
(12) Patent Application Publication
(10) Pub. No.: US 2020/0295304 A1
(43) Pub. Date: Sep. 17, 2020

(54) DISPLAY DEVICE

(71) Applicant: Japan Display Inc., Minato-ku (JP)

(72) Inventor: Tomohiko NAGANUMA, Minato-ku (JP)

(73) Assignee: Japan Display Inc., Minato-ku (JP)

(21) Appl. No.: 16/808,512

(22) Filed: Mar. 4, 2020

(30) Foreign Application Priority Data
Mar. 12, 2019 (JP) 2019-044795

(51) Int. Cl. H01L 51/52; H01L 27/32

(52) U.S. Cl. CPC H01L 51/5265; H01L 2251/5315; H01L 27/3244

(57) ABSTRACT

Layers interposed between a light emitting layer and pixel electrodes include an upper layer including at least one layer above a carrier generation layer and a lower layer including one or more layers below the carrier generation layer. The carrier generation layer has carrier mobility 100 times or higher than any one of one layer contacting a lower surface of the light emitting layer and one layer contacting a lower surface of the carrier generation layer. Light emitting sections are divided into groups corresponding to different light emitting colors. Each of the groups is different from at least one of the other groups in the distance that a corresponding group of the light emitting sections has from the lower surface of the light emitting layer to a reflective surface. First sections have a uniform thickness.

### CROSS-REFERENCE TO RELATED APPLICATION

The present application claims priority from Japanese patent application JP2019-044795 filed on Mar. 12, 2019, the content of which is hereby incorporated by reference into this application.

### BACKGROUND OF THE INVENTION

### 1. Field of the Invention

The present invention relates to a display device.

### 2. Description of the Related Art

In recent years, in a display device, adjacent pixels have come closer to each other as the number of pixels increases. An organic electroluminescence display may have a layer (for example, a hole injection layer) continuous to all pixels even though a light emitting layer is separated for each pixel.

The hole injection layer has a role of assisting hole injection from an anode to the light emitting layer. However, due to the low resistance, the hole injection layer causes a leak of holes to the adjacent pixels (lateral leakage), and causes weak light emission (electric color mixture) of pixels that should not be turned on. This leads to a reduction in display contrast and efficiency.

One factor that worsens the lateral leakage is that the driving voltages of red, green, and blue (RGB) elements are different. In general, RG elements have higher driving voltages than a B element since the thickness of the anode-side layer is thicker in the RG elements for the optical adjustment that brings out the microcavity effect. For this reason, the leakage current when the RG elements emit light easily causes the B element, which should not emit light. Although JP 2014-63829 A and JP 2004-514257 T disclose reducing the driving voltage, there is no disclosure of making the driving voltages of the RGB elements uniform.

### SUMMARY OF THE INVENTION

An object of the present invention is to make driving voltage uniform.

A display device according to the present invention includes a plurality of pixel electrodes each having a reflective surface, an electroluminescence layer placed in contact with the plurality of pixel electrodes, and a common electrode placed in contact with the electroluminescence layer, in which the electroluminescence layer includes a light emitting layer, and a plurality of layers interposed between the light emitting layer and the plurality of pixel electrodes; the plurality of layers include a carrier generation layer, an upper layer including at least one layer above the carrier generation layer, and a lower layer including one or more layers below the carrier generation layer; the carrier generation layer has carrier mobility 100 times or higher than any one of one layer contacting a lower surface of the light emitting layer and one layer contacting a lower surface of the carrier generation layer; the light emitting layer includes a plurality of light emitting sections respectively overlapping the plurality of pixel electrodes; the upper layer includes a plurality of first sections respectively overlapping the plurality of light emitting sections; the lower layer includes a plurality of second sections respectively overlapping the plurality of light emitting sections; the plurality of light emitting sections are divided into a plurality of groups corresponding to different light emitting colors, and each of the plurality of groups includes a corresponding group of the plurality of light emitting sections; each of the plurality of groups is different from at least one of the other groups in the distance that the corresponding group of the plurality of light emitting sections has from the lower surface of the light emitting layer to the reflective surface; and the plurality of first sections have a uniform thickness.

According to the present invention, since the thickness of the plurality of first sections is uniform, the distance from the carrier generation layer to the light emitting layer is uniform regardless of the light emitting color. Thus, the driving voltage can be made uniform.

### BRIEF DESCRIPTION OF THE DRAWINGS

FIG. 1 is a plan view of a display device according to an embodiment;

FIG. 2 is a schematic diagram showing a use state of the display device;

FIG. 3 is a schematic diagram of a cross section taken along line III-III of the display device shown in FIG. 2;

FIG. 4 is a partially enlarged view of a display area of the display device;

FIG. 5 is a cross-sectional view taken along line V-V of the display device shown in FIG. 4;

FIG. 6 is a cross-sectional view taken along line VI-VI of the display device shown in FIG. 4;

FIG. 7 is a circuit diagram of the display device shown in FIG. 1; and

FIG. 8 is a cross-sectional view of a display device according to a modification of the embodiment.

### DETAILED DESCRIPTION OF THE INVENTION

Hereinafter, embodiments of the present invention will be described with reference to the drawings. However, the present invention can be carried out in various modes without departing from the gist of the present invention, and is not to be construed as being limited to the description of the embodiments exemplified below.

The drawings may be schematically illustrated in terms of width, thickness, shape, and the like of each portion as compared with actual embodiments in order to make the description clearer, but are merely examples, and are not intended to limit the interpretation of the present invention. In the specification and the drawings, elements having the same functions as those described in relation to the already described drawings are denoted by the same reference numerals, and the redundant description may be omitted.

Furthermore, in the detailed description of the present invention, when defining the positional relationship between a certain component and another component, the terms “above” and “below” include not only the case where located directly above or below the certain component, but also the case where other components are further interposed therebetween unless otherwise specified.

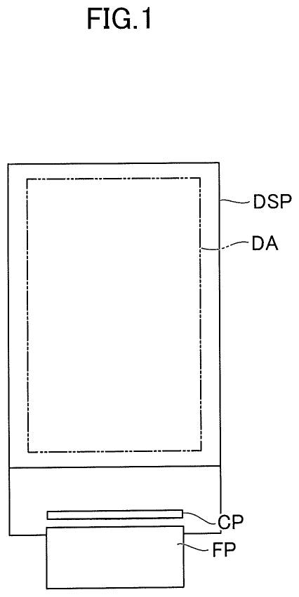

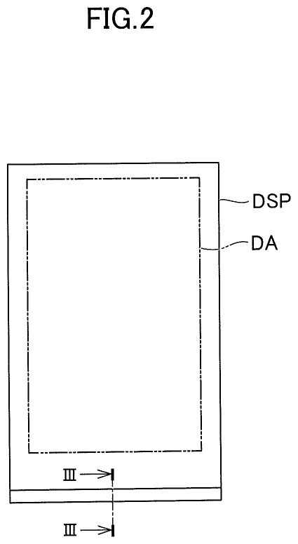

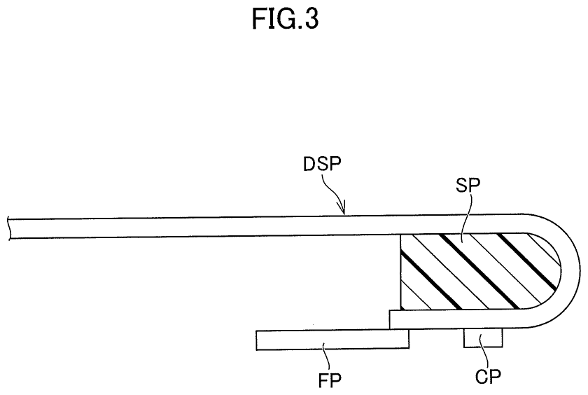

FIG. 1 is a plan view of a display device according to the embodiment. Since the display device is actually folded and used, FIG. 1 is a development view before the display device is folded. FIG. 2 is a schematic diagram illustrating a use state of the display device. FIG. 3 is a schematic diagram of a cross section taken along line III-III of the display device shown in FIG. 2.

The display device includes a display DSP. A spacer SP is arranged inside the bend to prevent the display DSP from being excessively bent. The display DSP has flexibility and is bent outside a display area DA. An integrated circuit chip CP for driving an element for displaying an image is mounted on the display DSP. A flexible printed circuit board FP is connected to the display DSP outside the display area DA.

The display device is, for example, an organic electroluminescence display device. The display device has the display area DA where an image is displayed. In the display area DA, for example, a full-color pixel is formed by combining unit pixels (sub-pixels) of a plurality of colors including red, green, and blue, and a full-color image is displayed.

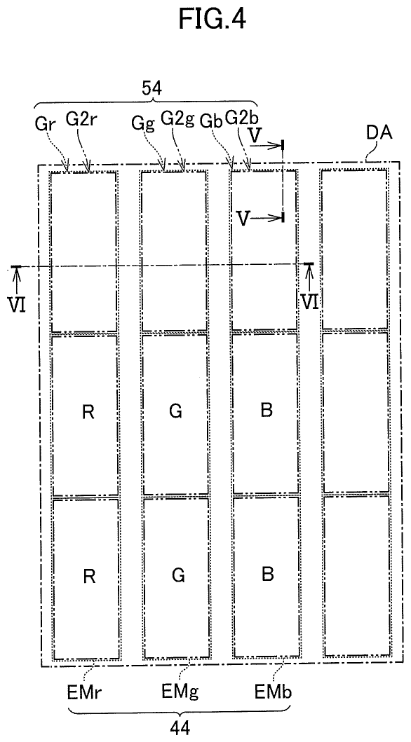

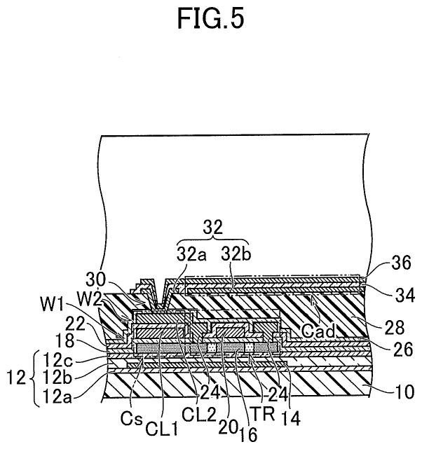

FIG. 4 is a partially enlarged view of the display area DA of the display device. FIG. 5 is a cross-sectional view taken along line V-V of the display device shown in FIG. 4.

A substrate 10 is made of polyimide. However, another resin material may be used as long as the substrate material has sufficient flexibility to constitute a sheet display or a flexible display.

On the substrate 10, a barrier inorganic film 12 (undercoat layer) is stacked. The barrier inorganic film 12 has a three-layer stacked structure of a silicon oxide film 12a, a silicon nitride film 12b, and a silicon oxide film 12c. The lowermost silicon oxide film 12a is provided for improving adhesion to the substrate 10, the intermediate silicon nitride film 12b is provided as a block film of moisture and impurities from the outside, and the uppermost silicon oxide film 12c is provided as a block film for preventing hydrogen atoms contained in the silicon nitride film 12b from diffusing to a semiconductor layer 16 side of a thin film transistor TR. However, the structure is not particularly limited to this structure, and may be further stacked, or may be a single layer or a two-layer stack.

A functional film 14 may be formed at a position where the thin film transistor TR is formed. The functional film 14 can suppress a change in the characteristics of the thin film transistor TR due to the intrusion of light from the back surface of the channel, or can give a back gate effect to the thin film transistor TR by being formed of a conductive material and giving a predetermined potential. Here, after forming the silicon oxide film 12a, the functional film 14 is formed in an island shape in accordance with the position where the thin film transistor TR is to be formed, and then the silicon nitride film 12b and the silicon oxide film 12c are stacked, and thus, the functional film 14 is formed to be sealed in the barrier inorganic film 12. The present invention is not limited thereto. The functional film 14 may be first formed on the substrate 10, and then the barrier inorganic film 12 may be formed.

The thin film transistor TR is formed on the barrier inorganic film 12. Only an Nch transistor is illustrated here by taking a polysilicon thin film transistor as an example, but a Pch transistor may be formed at the same time. The semiconductor layer 16 of the thin film transistor TR has a structure in which a low-concentration impurity region is provided between a channel region and a source and drain region. Here, a silicon oxide film is used as a gate insulating film 18. A gate electrode 20 is a part of a first wiring layer W1 formed of MoW. The first wiring layer W1 includes a first storage capacitance line CL1 in addition to the gate electrode 20. A part of a storage capacitance Cs is formed between the first storage capacitance line CL1 and the semiconductor layer 16 (source and drain region) via the gate insulating film 18.

On the gate electrode 20, an interlayer insulating film 22 (silicon oxide film and silicon nitride film) is stacked. On the interlayer insulating film 22, a second wiring layer W2 including a portion serving as a source and drain electrode 24 is formed. Here, a three-layer stacked structure of Ti, Al and Ti is employed. The first storage capacitance line CL1 (part of the first wiring layer W1) and a second storage capacitance line CL2 (part of the second wiring layer W2) form a part of another storage capacitance Cs via the interlayer insulating film 22.

A passivation film 26 is formed on the interlayer insulating film 22 so as to cover the second wiring layer W2 (source and drain electrode 24). On the passivation film 26, a planarizing film 28 is provided. The planarizing film 28 is made of a resin such as photosensitive acrylic because the resin has better surface planarization than an inorganic insulating material formed by chemical vapor deposition (CVD) or the like.

The planarizing film 28 and the passivation film 26 are removed at a pixel contact portion 30, and a conductive film 32 is formed thereon. The conductive film 32 is made of, for example, indium tin oxide (ITO). The conductive film 32 includes a first conductive film 32a and a second conductive film 32b separated from each other. The second wiring layer W2 whose surface is exposed by removing the planarizing film 28 and the passivation film 26 is covered with the first conductive film 32a. An inorganic insulating film 34 is provided on the planarizing film 28 so as to cover the first conductive film 32a. The inorganic insulating film 34 is made of, for example, an inorganic film such as a silicon nitride film. The inorganic insulating film 34 has an opening in the pixel contact portion 30, and a pixel electrode 36 is stacked so as to be electrically connected to the source and drain electrode 24 through the opening. The display device includes a plurality of pixel electrodes 36. The pixel electrode 36 extends laterally from the pixel contact portion 30 and reaches above the thin film transistor TR.

The second conductive film 32b is provided adjacent to the pixel contact portion 30, below the pixel electrode 36 (further below the inorganic insulating film 34). The second conductive film 32b, the inorganic insulating film 34, and the pixel electrode 36 are overlapped to form an additional capacitance Cad.

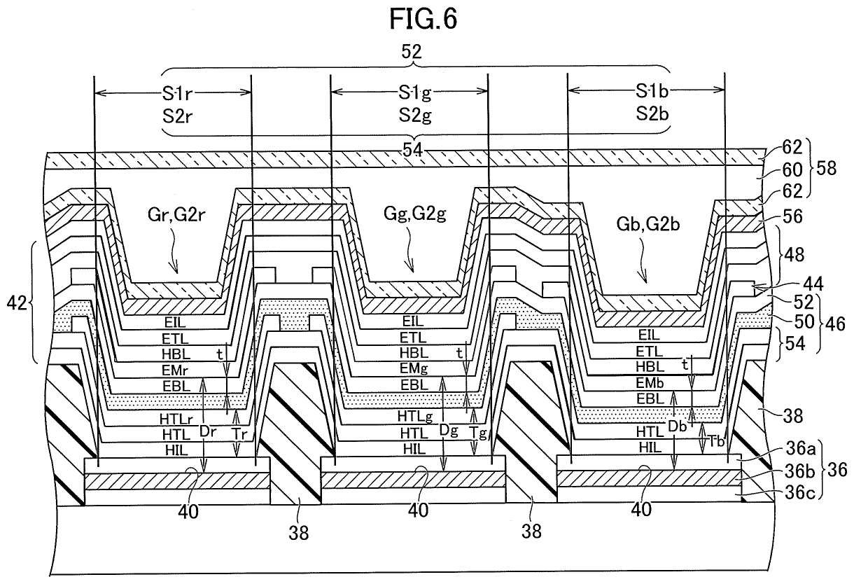

FIG. 6 is a cross-sectional view taken along line VI-VI of the display device shown in FIG. 4. On the planarizing film 28, an insulating layer 38 which is called a bank (rib) and serves as a partition wall between adjacent pixel regions is formed. As the insulating layer 38, a resin such as polyimide or photosensitive acrylic is used similarly to the planarizing film 28. The insulating layer 38 includes a plurality of openings such that the surfaces of the plurality of pixel electrodes 36 are exposed as light emitting regions. The insulating layer 38 is placed on the peripheral edge of each pixel electrode 36. The opening end of the opening preferably has a gentle taper shape.

The pixel electrode 36 is a reflective electrode having a reflective surface 40. For example, the pixel electrode 36 has a three-layer stacked structure of an indium zinc oxide film 36a, an Ag film 36b, and an indium zinc oxide film 36c. The indium zinc oxide films 36a and 36c are transparent, and the surface of the intermediate Ag layer 36b is the reflective surface 40. An indium tin oxide film may be used instead of the indium zinc oxide films 36a and 36c.

An electroluminescence layer 42 made of an organic material is stacked on the plurality of pixel electrodes 36. The electroluminescence layer 42 has a plurality of contact regions that respectively contact the plurality of pixel electrodes 36. The plurality of contact regions respectively overlap (or coincide with) the plurality of openings in the insulating layer 38. The electroluminescence layer 42 contacts the plurality of pixel electrodes 36 inside the plurality of openings. The electroluminescence layer 42 is placed on the insulating layer 38.

The electroluminescence layer 42 includes a light emitting layer 44. The light emitting layer 44 includes a plurality of light emitting sections EMr, EMg, and EMb that respectively overlap the plurality of pixel electrodes 36. The plurality of light emitting sections EMr, EMg, and EMb are divided into a plurality of groups Gr, Gg, and Gb corresponding to different light emitting colors. The light emitting colors include, for example, red, green, and blue (RGB). Each of the groups Gr, Gg, and Gb includes a corresponding group of the plurality of light emitting sections EMr, EMg, and EMb. A pair of adjacent light emitting sections (a pair of light emitting sections EMr, a pair of light emitting sections EMg, and a pair of light emitting sections EMb) in the common groups Gr, Gg, and Gb are continuous (see FIG. 4).

The electroluminescence layer 42 includes a first carrier adjustment layer 46 and a second carrier adjustment layer 48 respectively below and above the light emitting layer 44. The first carrier adjustment layer 46 and the second carrier adjustment layer 48 are for efficiently supplying carriers to the light emitting layer 44. In the first carrier adjustment layer 46 and the second carrier adjustment layer 48, the charges of the carriers to be supplied are opposite in polarity. In this embodiment, when the pixel electrode 36 is an anode, the carriers supplied by the first carrier adjustment layer 46 are holes, and the carriers supplied by the second carrier adjustment layer 48 are electrons.

### [First Carrier Adjustment Layer]

The first carrier adjustment layer 46 is interposed between the light emitting layer 44 and the plurality of pixel electrodes 36. The first carrier adjustment layer 46 has a thickness corresponding to the light emitting color of the light emitting section in order to obtain the microcavity effect. That is, in a microcavity structure in which the light generated in the light emitting section is reflected by the reflective surface 40 of the pixel electrode 36 and resonates, distances Dr, Dg, and Db from a lower surface of the light emitting layer 44 to the reflective surface 40 correspond to the wavelength of light. Thus, the thickness of the first carrier adjustment layer 46 is adjusted.

### [Carrier Generation Layer]

The first carrier adjustment layer 46 includes a carrier generation layer 50. The carrier generation layer 50 contains a host material and a guest material. The host material is doped with a guest material. The guest material is a dopant (acceptor) that supplies holes as a carrier, or a dopant (donor) that supplies electrons as a carrier. Boron is known as a p-type dopant.

The host material is the same as the material constituting one layer (a first carrier transport layer HTL or additional carrier transport layers HTLr and HTLg) that contacts a lower surface of the carrier generation layer 50. The carrier generation layer 50 has carrier mobility 100 times or higher than the one layer (the first carrier transport layer HTL or the additional carrier transport layers HTLr and HTLg) that contacts the lower surface thereof. Further, the carrier generation layer 50 has carrier mobility 100 times or higher than one layer (a first carrier block layer EBL) that contacts the lower surface of the light emitting layer 44. The carriers that have flowed out from the carrier generation layer 50 are supplied to the light emitting layer 44.

### [Upper Layer]

The first carrier adjustment layer 46 includes an upper layer 52 including at least one layer on the carrier generation layer 50. The upper layer 52 includes a plurality of first sections Sir, Sig, and Sib respectively overlapping the plurality of light emitting sections EMr, EMg, and EMb. The plurality of first sections Sir, Sig, and Sib have a uniform thickness t. Therefore, since the distance from the carrier generation layer 50 to the light emitting layer 44 is uniform regardless of the light emitting color, the driving voltage can be made uniform.

The uppermost layer of the first carrier adjustment layer 46 is the first carrier block layer EBL. The first carrier block layer EBL is the one layer that contacts the lower surface of the light emitting layer 44 and contacts an upper surface of the carrier generation layer 50. The first carrier block layer EBL is configured to block carriers whose charges are opposite in polarity to the carriers supplied from the carrier generation layer 50.

### [Lower Layer]

The first carrier adjustment layer 46 includes a lower layer 54 below the carrier generation layer 50. The lower layer 54 includes one or more layers. The lower layer 54 includes a plurality of second sections S2r, S2g, and S2b respectively overlapping the plurality of light emitting sections EMr, EMg, and EMb. The plurality of second sections S2r, S2g, and S2b are divided into a plurality of groups G2r, G2g, and G2b corresponding to different light emitting colors of the light emitting sections EMr, EMg, and EMb. Each of the plurality of groups G2r, G2g, and G2b includes a corresponding group of the plurality of second sections S2r, S2g, and S2b.

Each of the plurality of groups G2r, G2g, and G2b is different from at least one of the other groups in thicknesses Tr, Tg, and Tb of the corresponding group of the plurality of second sections S2r, S2g, and S2b. For example, the second section S2b belonging to the blue group G2b is thinner than the second sections S2r and S2g belonging to the red and green groups G2r and G2g (Tb<Tr, Tb<Tg). The second sections S2r and S2g belonging to the red and green groups G2r and G2g may have the same thickness (Tr=Tg) or may have different thicknesses (Tr≠Tg). As a result, the plurality of groups G2r, G2g, and G2b are different from at least one of the other groups in the distance that the corresponding group of the plurality of light emitting sections EMr, EMg, and EMb has from the lower, surface of the light emitting layer 44 to the reflective surface 40 (Db<Dr, Db<Dg).

The lowermost layer of the first carrier adjustment layer 46 is a first carrier injection layer HIL. The first carrier injection layer HIL is below the one layer that contacts the lower surface of the carrier generation layer 50. A lower surface of the first carrier injection layer HIL contacts the plurality of pixel electrodes 36. The first carrier injection layer HIL may have the same carrier mobility as the carrier generation layer 50, but is not limited thereto. That is, the first carrier injection layer HIL may have a lower doping concentration than the carrier generation layer 50.

The first carrier transport layer HTL is stacked on the first carrier injection layer HIL. Under the red and green light emitting sections EMr and EMg, the additional carrier transport layers HTLr and HTLg are respectively stacked on the first carrier transport layer HTL. The red additional carrier transport layer HTLr and the green additional carrier transport layer HTLg may have different thicknesses or may have the same thickness. No additional carrier transport layer is provided below the blue light emitting section EMb. Thus, the first carrier adjustment layer 46 has different thicknesses under the blue light emitting section EMb and under the red or green light emitting section EMr or EMg.

### [Second Carrier Adjustment Layer]

The uppermost layer of the second carrier adjustment layer 48 is a second carrier injection layer EIL. Under the second carrier injection layer EIL, a second carrier transport layer ETL is stacked. The lowermost layer of the second carrier adjustment layer 48 is a second carrier block layer HBL. The carriers that are blocked by the second carrier block layer HBL have a charge opposite in polarity to the carriers that are injected and transported by the second carrier injection layer EIL and the second carrier transport layer ETL. The light emitting layer 44 is provided in contact with a lower surface of the second carrier block layer HBL. The second carrier adjustment layer 48 may have a uniform thickness regardless of the light emitting colors of the light emitting sections EMr, EMg, and EMb.

Each of the layers constituting the electroluminescence layer 42 may be formed by vapor deposition, or may be formed by coating on a solvent dispersion, or may be formed selectively with respect to the pixel electrode 36 (each sub-pixel). Alternatively, the layer may be solidly formed on the entire surface covering the display area DA.

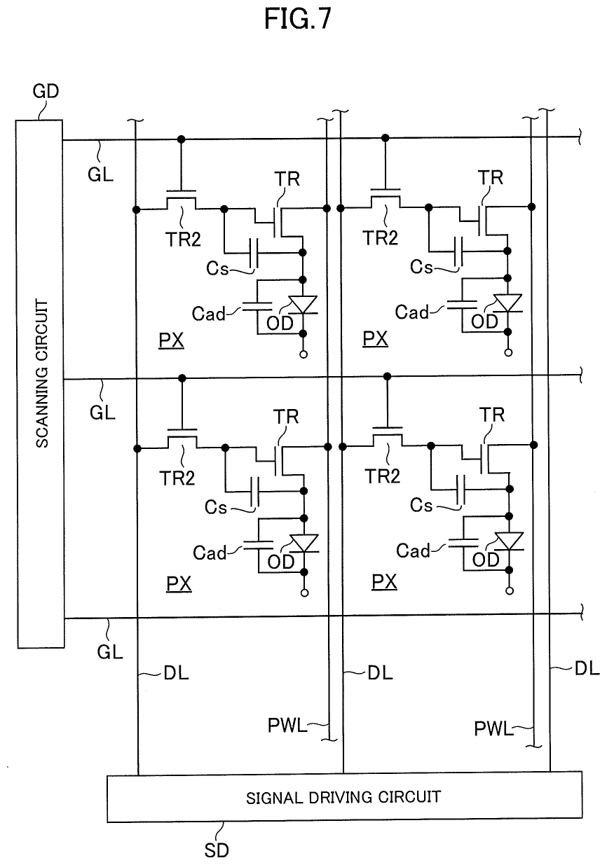

A common electrode 56 is provided on the electroluminescence layer 42. The common electrode 56 is placed in contact with the electroluminescence layer 42. Here, since the top emission structure is employed, the common electrode 56 is transparent. For example, an Mg layer and an Ag layer are formed as thin films to the extent that transmit the light emitted from the electroluminescence layer 42. If the pixel electrode 36 is an anode, the common electrode 56 is a cathode. The plurality of pixel electrodes 36, the common electrode 56, and the electroluminescence layer 42 interposed between the central portion of each of the plurality of pixel electrodes 36 and the common electrode 56 constitute one light emitting element OD (described below) for each pixel (See FIG. 7).

A sealing layer 58 is formed on the common electrode 56. One of the functions of the sealing layer 58 is to prevent moisture intrusion from the outside to the electroluminescence layer 42 formed earlier, and a high gas barrier property is required. The sealing layer 58 has a stacked structure of an organic film 60 and a pair of inorganic films 62 (for example, a silicon nitride film) sandwiching the organic film 60. An electrode for performing touch sensing may be further provided on the sealing layer 58, and a resin layer serving as a protective film and a polarizing plate (for example, a circular polarizing plate) may be stacked.

FIG. 7 is a circuit diagram of the display device shown in FIG. 1. The circuit includes a plurality of scanning lines GL to be connected to a scanning circuit GD and a plurality of signal lines DL to be connected to a signal driving circuit SD. The signal driving circuit SD is arranged in the integrated circuit chip CP shown in FIG. 1. A region surrounded by two adjacent scanning lines GL and two adjacent signal lines DL is one pixel PX. The pixel PX includes the thin film transistor TR as a driving transistor, a thin film transistor TR2 as a switch, and the storage capacitance Cs. When a gate voltage is applied to the scanning line GL, the thin film transistor TR2 is turned on, a video signal is supplied from the signal line DL, and the charge is accumulated in the storage capacitance Cs. When the charge is accumulated in the storage capacitance Cs, the thin film transistor TR is turned on, and a current flows from a power supply line PWL to the light emitting element OD. This current causes the light emitting element OD to emit light.

### [Modification]

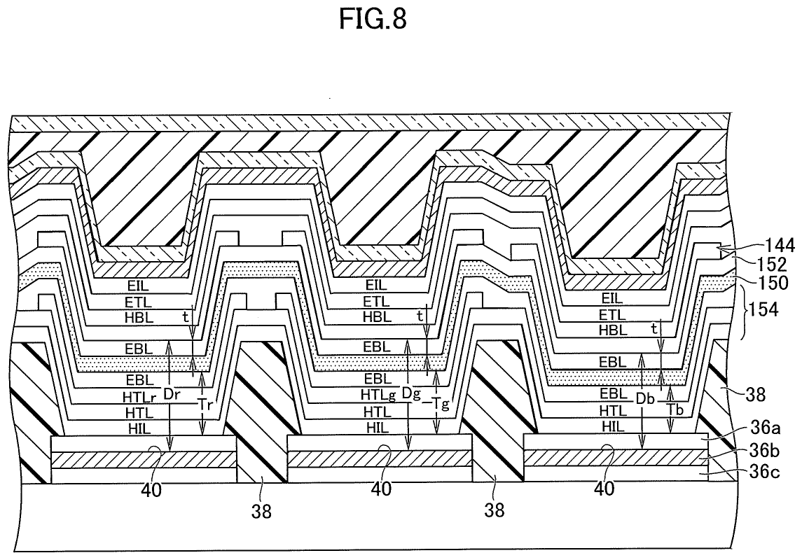

FIG. 8 is a cross-sectional view of a display device according to a modification of the embodiment. In this example, the first carrier block layer EBL is stacked respectively above and below a carrier generation layer 150. That is, the first carrier block layer EBL contacts an upper surface and a lower surface of the carrier generation layer 150, respectively. The host material of the carrier generation layer 150 is a material constituting the first carrier block layer EBL (one layer that contacts the lower surface and the upper surface of the carrier generation layer 150). In other words, the carrier generation layer 150 is formed by doping the first carrier block layer EBL with a guest material, and is also a carrier block layer. That is, the carrier generation layer 150 is an intermediate layer of a carrier block layer composed of a plurality of layers.

An upper layer 152 is formed of the first carrier block layer EBL that contacts the upper surface of the carrier generation layer 150. A lower layer 154 includes the first carrier block layer EBL that contacts the lower surface of the carrier generation layer 150.

The first carrier block layer EBL stacked on the upper surface of the carrier generation layer 150 contacts a lower surface of a light emitting layer 144. Therefore, the host material of the carrier generation layer 150 is also a material constituting one layer that contacts the lower surface of the light emitting layer 144. Other contents correspond to the contents described in the above embodiment.

While there have been described what are at present considered to be certain embodiments, it will be understood that various modifications may be made thereto, and it is intended that the appended claims cover all such modifications as fall within the true spirit and scope of the invention.

What is claimed is:

1. A display device, comprising:
a plurality of pixel electrodes each having a reflective surface;
an electroluminescence layer placed in contact with the plurality of pixel electrodes; and
a common electrode placed in contact with the electroluminescence layer, wherein
the electroluminescence layer includes a light emitting layer, and a plurality of layers interposed between the light emitting layer and the plurality of pixel electrodes,
the plurality of layers include a carrier generation layer, an upper layer including at least one layer above the carrier generation layer, and a lower layer including one or more layers below the carrier generation layer,
the carrier generation layer has carrier mobility 100 times or higher than any one of one layer contacting a lower surface of the light emitting layer and one layer contacting a lower surface of the carrier generation layer,
the light emitting layer includes a plurality of light emitting sections respectively overlapping the plurality of pixel electrodes,
the upper layer includes a plurality of first sections respectively overlapping the plurality of light emitting sections,
the lower layer includes a plurality of second sections respectively overlapping the plurality of light emitting sections,
the plurality of light emitting sections are divided into a plurality of groups corresponding to different light emitting colors, and each of the plurality of groups includes a corresponding group of the plurality of light emitting sections,
each of the plurality of groups is different from at least one of the other groups in the distance that the corresponding group of the plurality of light emitting sections has from the lower surface of the light emitting layer to the reflective surface, and
the plurality of first sections have a uniform thickness.

2. The display device according to claim 1, wherein
the plurality of second sections are divided into a plurality of groups corresponding to the different light emitting colors, and each of the plurality of groups includes a corresponding group of the plurality of second sections, and
each of the plurality of groups is different from at least one of the other groups in the thickness of the corresponding group of the plurality of second sections.

3. The display device according to claim 1, wherein
the one layer contacting the lower surface of the light emitting layer contacts an upper surface of the carrier generation layer.

4. The display device according to claim 1, wherein
the carrier generation layer is formed of a host material and a guest material, and
the host material is at least one of a material forming the one layer that contacts the lower surface of the light emitting layer and a material forming the one layer that contacts the lower surface of the carrier generation layer.

5. The display device according to claim 1, wherein
the lower layer includes a carrier injection layer that contacts the plurality of pixel electrodes below the one layer that contacts the lower surface of the carrier generation layer.

6. The display device according to claim 1, wherein
the one layer contacting the lower surface of the light emitting layer is configured to block a carrier whose charge is opposite in polarity to a carrier supplied from the carrier generation layer.
